(19) United States
(12) Patent Application Publication
(10) Pub. No.: US 2025/0138362 A1
(43) Pub. Date: May 1, 2025

(54) REFLECTIVE DISPLAY PANEL AND SPUTTERING TARGET

(71) Applicant: HannStar Display Corporation, Taipei City (TW)

(72) Inventors: Chiung-Chang Wu, Taipei City (TW); Hsien-Tang Hu, Taipei City (TW)

(73) Assignee: HannStar Display Corporation, Taipei City (TW)

(21) Appl. No.: 18/822,309

(22) Filed: Sep. 2, 2024

(30) Foreign Application Priority Data
Oct. 26, 2023 (TW) 112140949

(51) Int. Cl. G02F 1/1335; C22C 5/06; C23C 14/34; G02F 1/1333; G02F 1/1343; H01J 37/34

(52) U.S. Cl. CPC G02F 1/133553; C22C 5/06; C23C 14/3414; G02F 1/133345; G02F 1/134309; H01J 37/3426; G02F 2203/02

(57) ABSTRACT

A reflective display panel including a pixel structure is provided. The pixel structure has a reflective area and includes an active device, an insulation layer, and a reflective layer. The insulation layer is located above the active device. The reflective layer is disposed on the insulation layer and located in the reflective area. The reflective layer includes a silver alloy layer. A material of the silver alloy layer include silver with an atomic percentage greater than 96.5%, zinc with an atomic percentage greater than or equal to 0.1% and less than or equal to 2.0%, and antimony with an atomic percentage greater than or equal to 0.1% and less than or equal to 1.5%. A sputtering target adapted to deposit the silver alloy layer is further provided. A material of the sputtering target include silver with the atomic percentage greater than 96.5%, zinc with the atomic percentage greater than or equal to 0.1% and less than or equal to 2.0%, and antimony with the atomic percentage greater than or equal to 0.1% and less than or equal to 1.5%.

### CROSS-REFERENCE TO RELATED APPLICATION

This application claims the priority benefit of Taiwan application serial no. 112140949, filed on Oct. 26, 2023. The entirety of the above-mentioned patent application is hereby incorporated by reference herein and made a part of this specification.

### BACKGROUND

### Technical Field

The disclosure relates to a display panel and a process material, and more particularly, to a reflective display panel and a sputtering target.

### Description of Related Art

A reflective display panel mainly uses natural light or ambient light as a light source for display. Since it does not require backlight lighting for display, it has good energy-saving characteristics. Therefore, it is often used outdoors or in areas with sufficient light, such as outdoor billboards, electronic tags, sports watches, etc. Considering high reflectivity and low resistivity, silver is the first choice among all metallic elements as a reflective layer. However, since silver has poor chemical resistance, heat resistance, and weather resistance of silver, and has high electrochemical mobility, there are many issues and limitations in an application of silver.

### SUMMARY

The disclosure provides a reflective display panel, and a reflective layer thereof has better optical stability and durability.

The disclosure provides a sputtering target, and a film layer deposited by the sputtering target has better heat resistance and weather resistance.

A reflective display panel in the disclosure includes a pixel structure, and the pixel structure has a reflective area. The pixel structure includes an active device, an insulation layer, and a reflective layer. The insulation layer is located above the active device. The reflective layer is disposed on the insulation layer and located in the reflective area, and includes a silver alloy layer. A material of the silver alloy layer includes silver with an atomic percentage greater than 96.5%, zinc with an atomic percentage greater than or equal to 0.1% and less than or equal to 2.0%, and antimony with an atomic percentage greater than or equal to 0.1% and less than or equal to 1.5%.

In an embodiment of the disclosure, the reflective layer of the reflective display panel further includes a protective layer covering the silver alloy layer. A material of the protective layer includes a light-transmitting conductive material or a light-transmitting insulation material.

In an embodiment of the disclosure, the reflective layer of the reflective display panel further includes a buffer layer sandwiched between the insulation layer and the silver alloy layer.

A material of the buffer layer includes a conductive material.

A sputtering target in the disclosure is adapted to deposit the silver alloy layer. A material of the sputtering target includes silver with the atomic percentage greater than 96.5%, zinc with the atomic percentage greater than or equal to 0.1% and less than or equal to 2.0%, and antimony with the atomic percentage greater than or equal to 0.1% and less than or equal to 1.5%.

A reflective display panel in the disclosure includes a pixel structure, and the pixel structure has a reflective area. The pixel structure includes an active device, an insulation layer, and a reflective layer. The insulation layer is located above the active device. The reflective layer is disposed on the insulation layer and located in the reflective area, and includes a silver alloy layer. A material of the silver alloy layer includes silver with an atomic percentage greater than 95% and other elements with an atomic percentage less than or equal to 5%. The other elements include at least one of zinc, antimony, and neodymium with an atomic percentage greater than or equal to 0.1% and at least one of indium, tin, palladium, and gold with an atomic percentage greater than or equal to 0.1%.

In an embodiment of the disclosure, the other elements of the reflective display panel include zinc with an atomic percentage greater than or equal to 0.1% and less than or equal to 1.0%, tin with an atomic percentage greater than or equal to 0.1% and less than or equal to 1.5%, at least one of antimony, neodymium, and indium with an atomic percentage greater than or equal to 0.1% and less than or equal to 1.5%, and palladium or gold with an atomic percentage greater than or equal to 0.1% and less than or equal to 1.0%.

In an embodiment of the disclosure, the other elements of the reflective display panel include zinc with the atomic percentage greater than or equal to 0.1% and less than or equal to 1.0%, tin with the atomic percentage greater than or equal to 0.1% and less than or equal to 1.5%, at least one of antimony and neodymium with the atomic percentage greater than or equal to 0.1% and less than or equal to 1.5%, and palladium or gold with the atomic percentage greater than or equal to 0.1% and less than or equal to 1.0%.

In an embodiment of the disclosure, the other elements of the reflective display panel include zinc with the atomic percentage greater than or equal to 0.1% and less than or equal to 1.0%, tin with the atomic percentage greater than or equal to 0.1% and less than or equal to 1.5%, antimony with the atomic percentage greater than or equal to 0.1% and less than or equal to 1.5%, and palladium or gold with the atomic percentage greater than or equal to 0.1% and less than or equal to 1.0%.

In an embodiment of the disclosure, the pixel structure of the reflective display panel further includes a pixel electrode and another insulation layer. The pixel electrode is disposed above the reflective layer. The pixel electrode overlaps the reflective layer. The another insulation layer is sandwiched between the pixel electrode and the reflective layer.

In an embodiment of the disclosure, the reflective layer of the reflective display panel further includes a protective layer. The protective layer covers the silver alloy layer. A material of the protective layer includes a light-transmitting conductive material or a light-transmitting insulation material.

In an embodiment of the disclosure, the reflective layer of the reflective display panel further includes a buffer layer sandwiched between the insulation layer and the silver alloy layer. A material of the buffer layer includes a conductive material.

A sputtering target in the disclosure is adapted to deposit the silver alloy layer. A material of the sputtering target includes silver with the atomic percentage greater than 95% and other elements with the atomic percentage less than or equal to 5%, and the other elements includes at least one of zinc, antimony, and neodymium with an atomic percentage greater than or equal to 0.1% and at least one of indium, tin, palladium, and gold with an atomic percentage greater than or equal to 0.1%.

Based on the above, in the reflective display panel according to an embodiment of the disclosure, the material of the sputtering target configured to deposit the reflective layer, in addition to silver with the atomic percentage greater than 96.5%, further includes zinc with the atomic percentage greater than or equal to 0.1% and less than or equal to 2.0% and antimony with the atomic percentage greater than or equal to 0.1% and less than or equal to 1.5%. Therefore, the heat resistance of the silver alloy layer deposited by the sputtering target may be significantly improved, thereby increasing the optical stability and durability of the reflective layer. In the reflective display panel according to another embodiment of the disclosure, the material of the sputtering target configured to deposit the reflective layer, in addition to silver with the atomic percentage greater than 95%, further includes other elements with the atomic percentage less than or equal to 5%. The other elements include at least one of zinc, antimony, and neodymium with the atomic percentage greater than or equal to 0.1% and at least one of indium, tin, palladium, and gold with the atomic percentage greater than or equal to 0.1%. Therefore, the silver alloy layer deposited by the sputtering target may not only significantly improve the heat resistance, but also effectively improve the weather resistance and resistance to halogen and sulfur of the silver alloy layer, thereby maintaining the optical properties of the silver alloy layer and improve the process yield.

### BRIEF DESCRIPTION OF THE DRAWINGS

FIG. 1 is a schematic cross-sectional view of a reflective display panel according to the first embodiment of the disclosure.

FIG. 2 is a schematic cross-sectional view of a pixel structure of the reflective display panel according to the first embodiment of the disclosure.

FIG. 3A is an enlarged cross-sectional view of a reflective layer in FIG. 2.

FIG. 3B is an enlarged cross-sectional view of a reflection layer in FIG. 2 according to another modified embodiment.

FIG. 4 is a partial flowchart of a manufacturing method of the reflective display panel according to the first embodiment of the disclosure.

FIGS. 5A to 5D are schematic views of the manufacturing method in FIG. 4.

FIGS. 6A to 6D are schematic views of forming a buffer material layer, a silver alloy material layer, and a protection material layer in a reflective material layer in a same process apparatus according to the first embodiment of the disclosure.

FIG. 7 is a partial flowchart of a manufacturing method of a reflective display panel according to the second embodiment of the disclosure.

FIG. 8 is a schematic view of forming a silver alloy material layer and a protection material layer in a reflective material layer in two process apparatuses respectively according to the second embodiment of the disclosure.

FIG. 9A is an enlarged cross-sectional view of a reflective layer of a reflective display panel according to a modified embodiment of the second embodiment of the disclosure.

FIG. 9B is an enlarged cross-sectional view of a reflective layer of a reflective display panel according to another modified embodiment of the second embodiment of the disclosure.

FIG. 10 is a partial flowchart of a manufacturing method of the reflective display panel having the reflective layer in FIG. 9A or 9B.

FIGS. 11A to 11C are schematic views of the manufacturing method in FIG. 10.

FIG. 12 is a schematic cross-sectional view of a reflective display panel according to the third embodiment of the disclosure.

FIG. 13 is a schematic cross-sectional view of a pixel structure of the reflective display panel according to the third embodiment of the disclosure.

FIG. 14 is a schematic cross-sectional view of a pixel structure of a reflective display panel according to the fourth embodiment of the disclosure.

FIG. 15 is an enlarged cross-sectional view of a reflective layer in FIG. 14.

### DETAILED DESCRIPTION OF DISCLOSED EMBODIMENTS

Reference will now be made in detail to the exemplary embodiments of the disclosure, and examples of the exemplary embodiments are illustrated in the accompanying drawings. Whenever possible, the same reference numerals are used in the drawings and descriptions to indicate the same or similar parts.

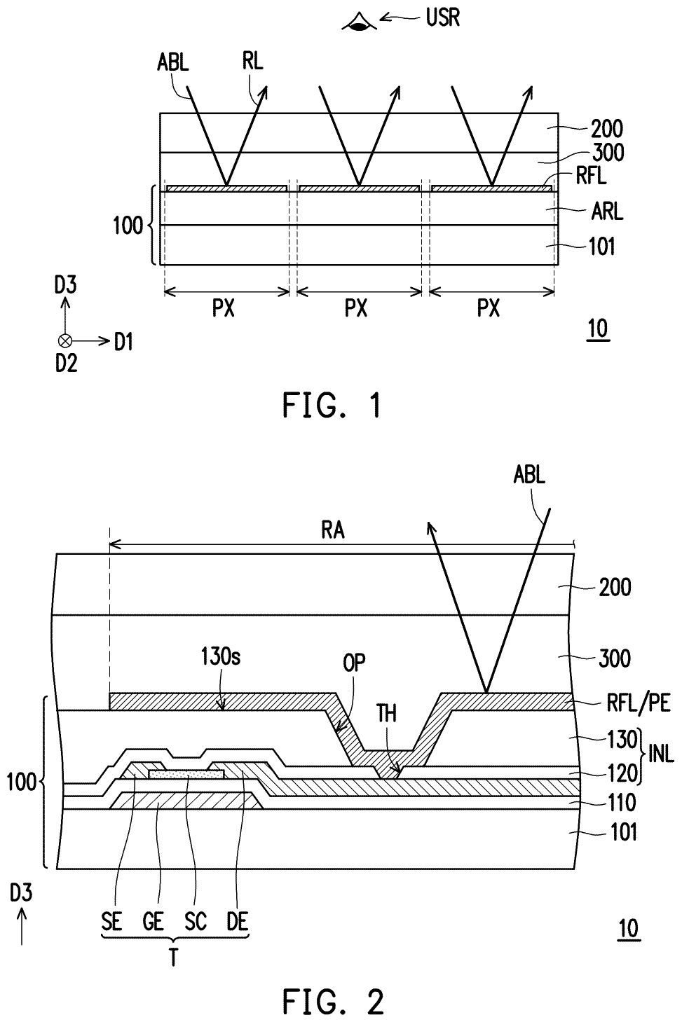

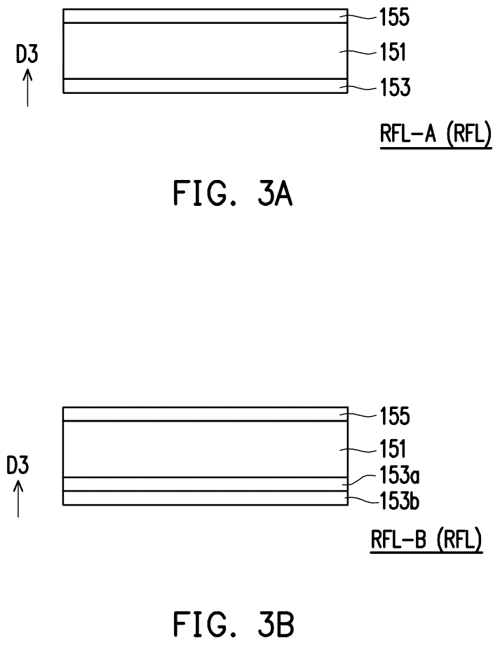

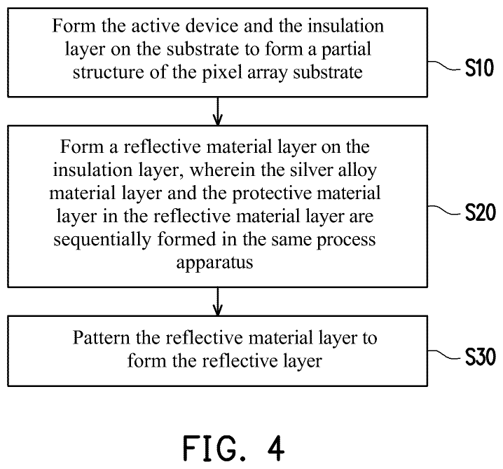

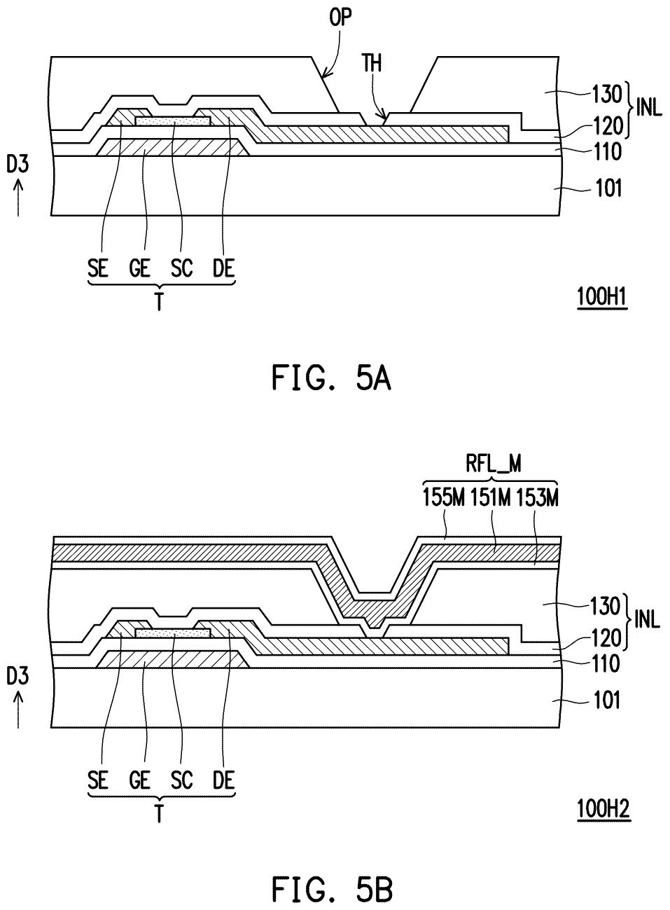

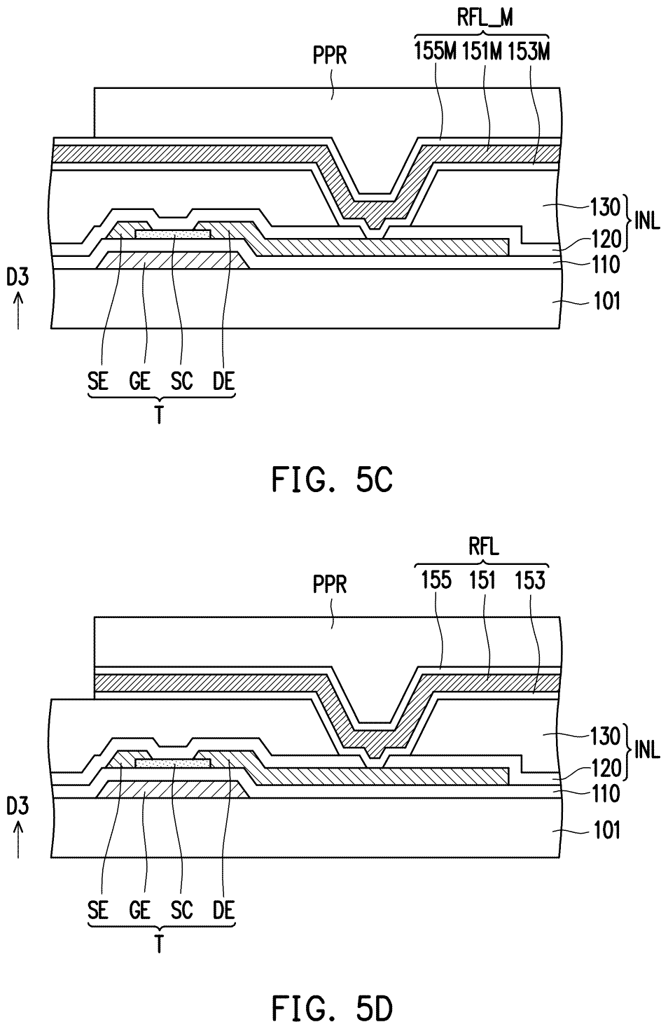

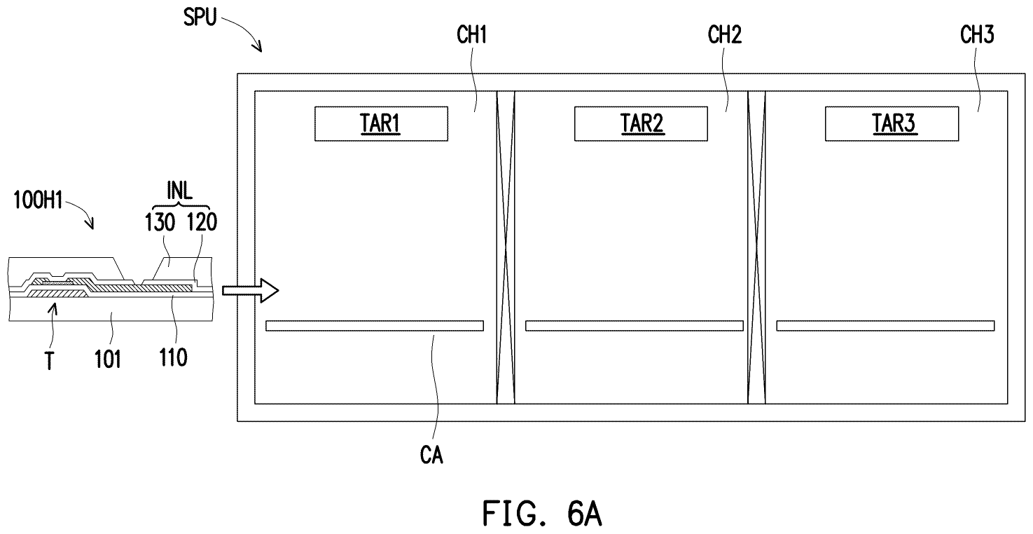

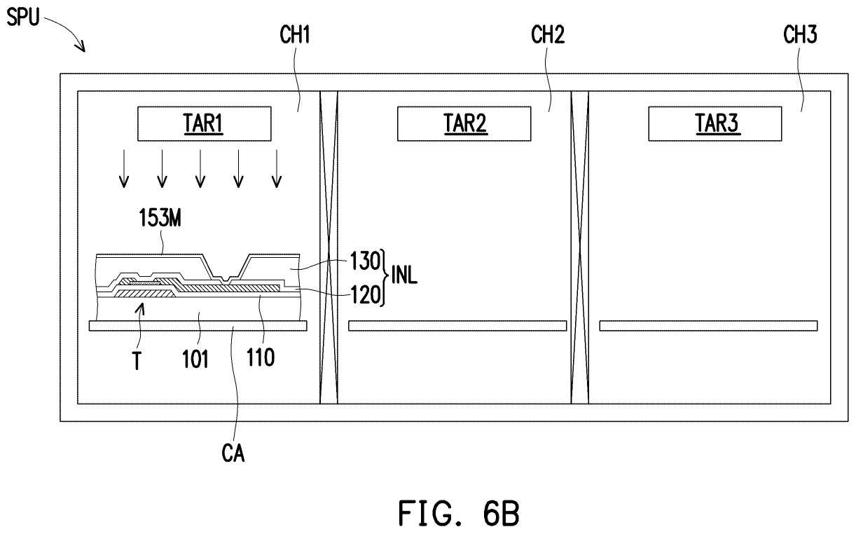

FIG. 1 is a schematic cross-sectional view of a reflective display panel according to the first embodiment of the disclosure. FIG. 2 is a schematic cross-sectional view of a pixel structure of the reflective display panel according to the first embodiment of the disclosure. FIG. 3A is an enlarged cross-sectional view of a reflective layer in FIG. 2. FIG. 3B is an enlarged cross-sectional view of a reflection layer in FIG. 2 according to another modified embodiment. FIG. 4 is a partial flowchart of a manufacturing method of the reflective display panel according to the first embodiment of the disclosure. FIGS. 5A to 5D are schematic views of the manufacturing method in FIG. 4. FIGS. 6A to 6D are schematic views of forming a buffer material layer, a silver alloy material layer, and a protection material layer in a reflective material layer in a same process apparatus according to the first embodiment of the disclosure.

Referring to FIG. 1, a reflective display panel 10 includes a pixel array substrate 100. In this embodiment, the pixel array substrate 100 may include a substrate 101 and multiple pixel structures PX. The pixel structures PX are arranged in an array (not shown) on the substrate 101. Although FIG. 1 only shows the pixel structures PX of the pixel array substrate 100 arranged along a first direction D1, it may be understood that the pixel structures PX may be arranged in an array on the substrate 101. For example, the pixel structures PX may be arranged in multiple rows and columns along two directions perpendicular to each other (such as the first direction D1 and a second direction D2). A material of the substrate 101 may include glass, quartz, high molecular polymer (such as polyimide, polycarbonate, polymethyl methacrylate, or other suitable flexible sheets), or other suitable sheets. Referring to FIGS. 1 and 2, a pixel array layer ARL is disposed on the substrate 101, and a reflective layer RFL is disposed on the pixel array layer ARL. The pixel array layer ARL includes an active device and an insulation layer (such as an active device T and an insulation layer INL in FIG. 2), and a material of the reflective layer RFL includes metal with high reflectivity, such as metal alloy containing silver. Incident light ABL is reflected by the reflective layer RFL to form reflective light RL, so as to form a corresponding image in eyes of a user USR. In this embodiment, the incident light ABL may be ambient light, light from a front light module, or a combination thereof. In this embodiment, the pixel array substrate 100 includes the substrate 101, the pixel array layer ARL, and the reflective layers RFL. In addition, in some embodiments, the pixel array substrate 100 may further include an alignment layer (not shown) disposed on the pixel array layer ARL and the reflective layers RFL, and the alignment layer is configured to align multiple liquid crystal molecules (not shown) of a liquid crystal layer (i.e., a display medium layer 300). A material of the alignment layer may include polyimide or other suitable materials.

In this embodiment, a method of forming the active device T may include the following steps. A gate GE, a gate insulation layer 110, a semiconductor pattern SC, a source SE, and a drain DE are sequentially formed on the substrate 101. The semiconductor pattern SC overlaps the gate GE. The source SE and the drain DE overlap the semiconductor pattern SC, and are in electrical contact with two different areas of the semiconductor pattern SC. In this embodiment, the gate GE of the active device T may be selectively disposed below the semiconductor pattern SC to form a bottom-gate TFT, but the disclosure is not limited thereto. In other embodiments, the gate of the active device may also be selectively disposed above the semiconductor pattern to form a top-gate TFT.

It should be noted that the gate GE, the source SE, the drain DE, the semiconductor pattern SC, and the gate insulation layer 110 may be respectively implemented by any gate, any source, any drain, any semiconductor pattern, and any gate insulation layer known to those skilled in the art for the reflective display panel, and the gate GE, the source SE, the drain DE, the semiconductor pattern SC, and the gate insulation layer 110 may be formed by any method known to those skilled in the art. Therefore, the same details will not be repeated in the following.

Furthermore, the reflective display panel 10 further includes the insulation layer INL. In this embodiment, the insulation layer INL includes a passivation layer 120 and a flat layer 130, but the disclosure is not limited thereto. In some embodiments, the insulation layer INL may be a single-layer structure and include only the passivation layer 120 or the flat layer 130. The passivation layer 120 covers the active devices T of the pixel structures PX. The flat layer 130 covers the passivation layer 120. In this embodiment, a material of the flat layer 130 may be an organic material, and a material of the passivation layer 120 may be an inorganic material. In addition, the passivation layer 120 is located between the flat layer 130 and a metal layer (such as the source SE and the drain DE of the active device T) to prevent the flat layer 130 and the metal layer from peeling off due to poor adhesion, but the disclosure is not limited thereto. A pixel electrode PE of the pixel structure PX is disposed on a surface 130s of the flat layer 130 facing away from the substrate 101, and is electrically connected to the drain DE of the active device T through an opening OP of the flat layer 130 and a contact hole TH of the passivation layer 120.

For example, the reflective display panel 10 may further include another substrate 200 and the display medium layer 300. The display medium layer 300 is disposed between the pixel array substrate 100 and the substrate 200. In this embodiment, the display medium layer 300 is, for example, a liquid crystal layer. That is, the reflective display panel 10 in this embodiment may be a reflective liquid crystal display panel, but the disclosure is not limited thereto.

On the other hand, the substrate 200 may be provided with a color filter layer (not shown) and/or a common electrode layer (not shown), but the disclosure is not limited thereto. In some embodiments, the common electrode layer may be disposed in the pixel array substrate 100. An electric field generated between the common electrode layer and the pixel electrode PE is adapted to drive the liquid crystal molecules (not shown) of the liquid crystal layer (i.e., the display medium layer 300) to rotate to form an arrangement state corresponding to a direction and intensity of the electric field. By changing the arrangement state of the liquid crystal molecules, polarization states of the incident light ABL and the reflective light RL passing through the liquid crystal layer is changed to form an output light brightness of the reflective display panel 10 corresponding to the arrangement state. In addition, in some embodiments, the reflective display panel 10 may further include another alignment layer (not shown) disposed on a surface of the substrate 200 facing the display medium layer 300, and the another alignment layer is configured to align the liquid crystal molecules (not shown) of the liquid crystal layer (i.e., the display medium layer 300).

In this embodiment, the pixel electrode PE is, for example, a reflective electrode formed by a metal alloy material containing silver. That is, the pixel electrode PE in this embodiment also serves as the reflective layer RFL of the reflective display panel 10, and the reflective layer RFL includes a silver alloy layer. Therefore, in this embodiment, the pixel structure PX includes the active device T, the insulation layer INL, and the reflective layer RFL, and the reflective layer RFL is located in a reflective area RA of the pixel structure PX.

Referring to FIGS. 2 and 3A, a reflective layer RFL-A includes a silver alloy layer 151. In order to improve adhesion between the silver alloy layer 151 and the insulation layer INL, the reflective layer RFL may further selectively include a buffer layer 153 sandwiched between the flat layer 130 and the silver alloy layer 151. The buffer layer 153 is a conductive layer, and a material of the buffer layer 153 may be a light-transmitting or opaque conductive material. For example, the material of the buffer layer 153 includes ITO, IZO, Mo, MoOx, MoTa, AlNd, or Ti. However, the disclosure is not limited thereto. In another modified embodiment, the number of buffer layers of the reflective layer RFL may also be multiple (such as a buffer layer 153a and a buffer layer 153b in a reflective layer RFL-B in FIG. 3B). That is, the buffer layer of the reflective layer RFL may be a stacked structure of multiple buffer layers, and materials of the buffer layers may be different.

On the other hand, in order to prevent the silver alloy layer 151 from being exposed to the air for a long time, causing material deterioration (for example, the silver alloy layer 151 is sulfurized and/or oxidized) and affecting optical properties (for example, colors of the silver alloy layer 151 changes and/or a reflectivity decreases), the reflective layer RFL may further selectively include a protective layer 155 covering the silver alloy layer 151. A material of the protective layer 155 may be a light-transmitting material, so that at least a portion of the incident light ABL may penetrate through the protective layer 155 to reach the silver alloy layer 151, and the light reflected by the silver alloy layer 151 may penetrate through the protective layer 155 to form at least a portion of the reflective light RL. In addition, the protective layer 155 may be a conductive layer or a non-conductive layer. For example, the material of the protective layer 155 includes ITO, IZO, SiO₂, SiNₓ, SiOₓN_{y}, or Al₂O₃.

Referring to FIG. 4, a portion of a manufacturing method of the reflective display panel 10 includes steps S10 to S30. Referring to FIGS. 4 and 5A, in step S10, the active device T and the insulation layer INL are formed on the substrate 101 to form a partial structure 100H1 of the pixel array substrate. The flat layer 130 has the opening OP, and the passivation layer 120 has the contact hole TH. Referring to FIGS. 4 and 5B, next, step S20 is performed. In step S20, a reflective material layer RFL_M is formed on the insulation layer INL to form a partial structure 100H2 of the pixel array substrate, and the reflective material layer RFL_M includes a buffer material layer 153M, a silver alloy material layer 151M, and a protective material layer 155M. The silver alloy material layer 151M and the protective material layer 155M in the reflective material layer RFL_M are sequentially formed in the same process apparatus. In this embodiment, the silver alloy material layer 151M and the protective material layer 155M in the reflective material layer RFL_M are formed by continuous coating in the same process apparatus (such as a sputtering apparatus). That is, after the silver alloy material layer 151M is formed, the protective material layer 155M for protecting the silver alloy material layer 151M may be formed on the silver alloy material layer 151M without moving a substrate with the silver alloy material layer 151M out of the process apparatus. Therefore, the silver alloy material layer 151M may be prevented from being exposed to the air and being sulfurized and/or oxidized. In this embodiment, the buffer material layer 153M and the silver alloy material layer 151M in the reflective material layer RFL_M may be formed sequentially in the same process apparatus, or formed separately in two process apparatuses.

For example, as shown in FIGS. 6A to 6D, the partial structure 100H1 of the pixel array substrate in FIG. 5A may be transmitted to a sputtering apparatus SPU to form the reflective material layer RFL_M. The reflective material layer RFL_M includes the buffer material layer 153M, the silver alloy material layer 151M, and the protective material layer 155M. Materials of the buffer material layer 153M, the silver alloy material layer 151M, and the protective material layer 155M may be, for example, ITO, silver alloy, and ITO respectively. The sputtering apparatus SPU includes three sputtering chambers CH1, CH2, and CH3, and the sputtering chambers CH1, CH2, and CH3 are respectively configured to sputter to form the buffer material layer 153M, the silver alloy material layer 151M, and the protective material layer 155M. The partial structure 100H1 of the pixel array substrate in FIG. 5A is transmitted to the chamber CH1 in the sputtering apparatus SPU (as shown in FIG. 6A). The partial structure 100H1 of the pixel array substrate is located on a carrier CA. An ITO target TAR1 is disposed in the chamber CH1, and the buffer material layer 153M is formed on the insulation layer INL by using a sputtering process (as shown in FIG. 6B). Next, the partial structure of the pixel array substrate in FIG. 6B is transmitted to the chamber CH2 in the sputtering apparatus SPU. A silver alloy target TAR2 is disposed in the chamber CH2, and the silver alloy material layer 151M is formed on the buffer material layer 153M by using the sputtering process (as shown in FIG. 6C). Then, the partial structure of the pixel array substrate in FIG. 6C is transmitted to the chamber CH3 in the sputtering apparatus SPU. An ITO target TAR3 is disposed in the chamber CH3, and the protective material layer 155M is formed on the silver alloy material layer 151M by using the sputtering process (as shown in FIG. 6D) to form the partial structure 100H2 of the pixel array substrate in FIG. 5B. Next, the partial structure 100H2 of the pixel array substrate is removed from the sputtering apparatus SPU (not shown). The sputtering apparatus SPU shown in FIGS. 6A to 6D is only an example, and in this embodiment, the type of the process apparatus used for continuous coating is not limited. For example, the sputtering apparatus may have a chamber. The partial structure 100H1 of the pixel array substrate in FIG. 5A is transmitted to the chamber of the sputtering apparatus. The ITO target TAR1, the silver alloy target TAR2, and the ITO target TAR3 may be sequentially transmitted to the chamber to sequentially form the buffer material layer 153M, the silver alloy material layer 151M, and the protective material layer 155M on the insulation layer INL, which may also prevent the silver alloy material layer 151M from being exposed to the air and being sulfurized and/or oxidized.

Referring to FIGS. 4, 5C, and 5D, next, step S30 is performed. In step S30, the reflective material layer RFL_M in a structure of FIG. 5B is patterned to form the reflective layer RFL. For example, a pattern photoresist layer PPR (as shown in FIG. 5C) may be formed on the reflective material layer RFL_M, and the reflective material layer RFL_M is patterned through an etching process to form the reflective layer RFL (as shown in FIG. 5D). The buffer material layer 153M, the silver alloy material layer 151M, and the protective material layer 155M in the reflective material layer RFL_M are patterned respectively to form the buffer layer 153, the silver alloy layer 151, and the protective layer 155 in the reflective layer RFL. Therefore, the materials of the buffer material layer 153M, the silver alloy material layer 151M, and the protective material layer 155M are respectively the same as the materials of the buffer layer 153, the silver alloy layer 151, and the protective layer 155.

In particular, the protective material layer 155M and the silver alloy material layer 151M are manufactured in the same process apparatus. However, in order to avoid a phenomenon that silver in the previously formed silver alloy material layer 151M is condensed due to thermal diffusion during a film formation process of the protective material layer 155M, resulting in a decrease in reflectivity, a material of a sputtering target configured to deposit the silver alloy layer 151 (i.e., the sputtering target configured to deposit the silver alloy material layer 151M, such as the silver alloy target TAR2 in FIG. 6C) may include silver with an atomic percentage greater than 96.5%, zinc with an atomic percentage greater than or equal to 0.1% and less than or equal to 2.0%, and antimony with an atomic percentage greater than or equal to 0.1% and less than or equal to 1.5%. That is to say, material composition of the silver alloy material layer 151M and the silver alloy layer 151 in this embodiment further includes, in addition to silver with the atomic percentage greater than 96.5%, zinc with the atomic percentage greater than or equal to 0.1% and less than or equal to 2.0% and antimony with the atomic percentage greater than or equal to 0.1% and less than or equal to 1.5%. Based on the above, in this embodiment, the materials of the sputtering target configured to deposit the silver alloy layer 151, the silver alloy material layer 151M, and the silver alloy layer 151 may include silver with the atomic percentage greater than 96.5% and other elements with an atomic percentage less than or equal to 3.5%. The other elements include zinc with the atomic percentage greater than or equal to 0.1% and less than or equal to 2.0% and antimony with the atomic percentage greater than or equal to 0.1% and less than or equal to 1.5%.

In this embodiment, addition of zinc and antimony may improve heat resistance of the silver alloy layer 151, and addition of zinc may also improve reflectivity of the silver alloy layer 151 to short-wavelength light. Therefore, by adding zinc with an atomic percentage greater than or equal to 0.1% and antimony with an atomic percentage greater than or equal to 0.1%, the heat resistance and reflectivity to the short-wavelength light of the silver alloy layer 151 may be effectively improved, thereby ensuring that a reflective surface of the silver alloy material layer 151M may still maintain smaller surface roughness and better reflectivity after the film formation process of the protective material layer 155M. On the other hand, in the sputtering target configured to deposit the silver alloy layer 151, the silver alloy material layer 151M, and the silver alloy layer 151 in this embodiment, a sum of the atomic percentages of elements other than silver may not exceed 3.5% (that is, the sum of the atomic percentages of elements other than silver is less than or equal to 3.5%) to prevent the overall reflectivity of the silver alloy layer 151 from decreasing due to excessive addition of other elements.

In addition, although zinc and antimony significantly improve the heat resistance of the silver alloy material layer 151M, they still have a certain tolerance to subsequent processes containing halogen and sulfur. That is to say, an edge portion of the silver alloy material layer 151M exposed during patterning and after patterning still has the ability to resist subsequent processes and environmental pollution containing halogen and sulfur, thereby increasing optical stability and durability of the reflective layer RFL.

Some other embodiments are provided below to describe the invention in detail, where the same reference numerals denote the same or like components, and descriptions of the same technical contents are omitted. The aforementioned embodiment may be referred for descriptions of the omitted parts, and detailed descriptions thereof are not repeated in the following embodiment.

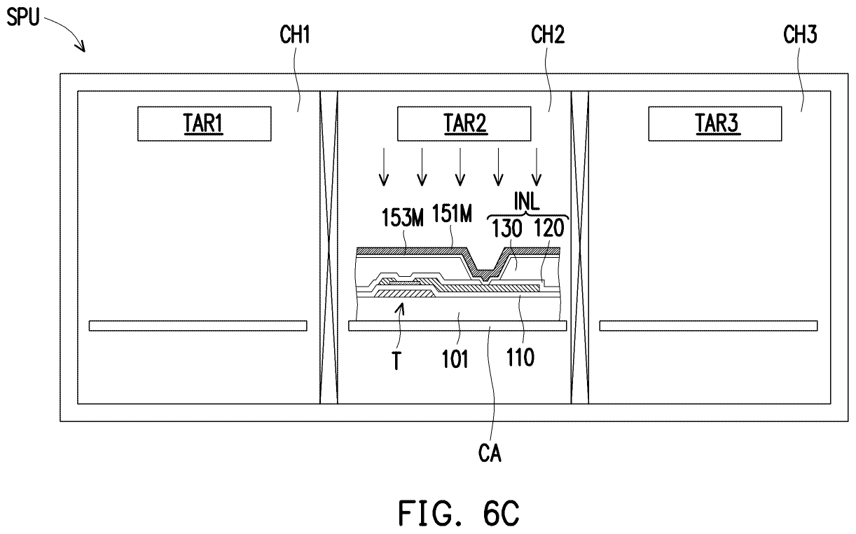

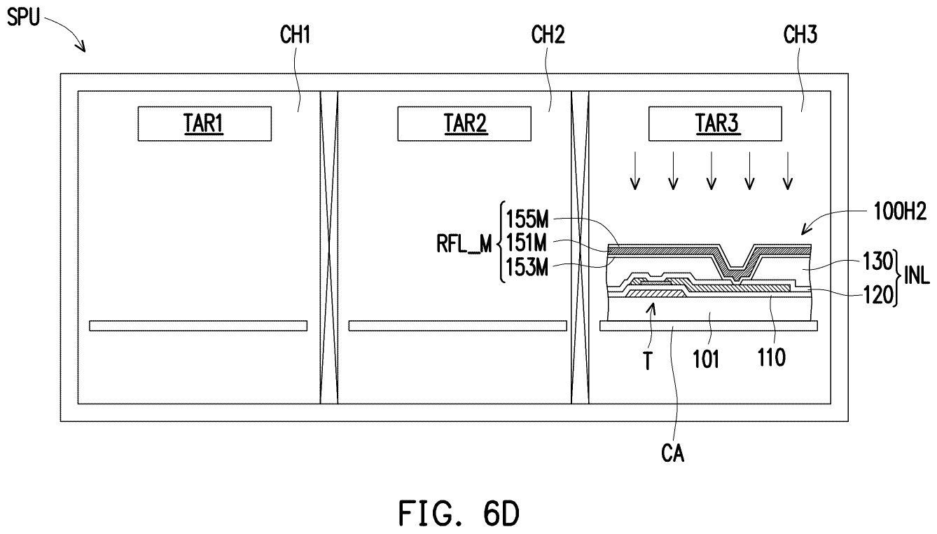

FIG. 7 is a partial flowchart of a manufacturing method of a reflective display panel according to the second embodiment of the disclosure. FIG. 8 is a schematic view of forming a silver alloy material layer and a protection material layer in a reflective material layer in two process apparatuses respectively according to the second embodiment of the disclosure.

Structures of the reflective display panel in the second embodiment and the first embodiment are the same as each other (for example, they are both the reflective display panel 10 in FIG. 2). However, methods of forming the silver alloy material layer 151M and the protective material layer 155M of the reflective material layer RFL_M in the second embodiment and the first embodiment are different from each other, and the elemental composition and range of the silver alloy layer 151 of the reflective layer RFL in the second embodiment and the first embodiment (i.e., the elemental composition and range of the silver alloy material layer 151M and the elemental composition and range of the sputtering target configured to deposit the silver alloy layer 151) are different from each other.

Referring to FIGS. 2 and 7, a portion of the manufacturing method of the reflective display panel 10 includes steps S10′ to S30′. Referring to FIGS. 7 and 5A, in step S10′, the active device T and the insulation layer INL are formed on the substrate 101 to form the partial structure 100H1 of the pixel array substrate. Referring to FIGS. 7 and 5B, next, step S20′ is performed. In step S20′, the reflective material layer RFL_M is formed on the insulation layer INL to form the partial structure 100H2 of the pixel array substrate, and the reflective material layer RFL_M includes the buffer material layer 153M, the silver alloy material layer 151M, and the protective material layer 155M. The silver alloy material layer 151M and the protective material layer 155M in the reflective material layer RFL_M are formed in the two process apparatuses respectively. Therefore, after the silver alloy material layer 151M is formed in one process apparatus and before being transmitted to the another process apparatus to form the protective material layer 155M, the silver alloy material layer 151M will be exposed to the air.

For example, as shown in FIG. 8, after the silver alloy material layer 151M is formed on the buffer material layer 153M by using the silver alloy target TAR2 in a sputtering apparatus SPU1, the partial structure of the pixel array substrate having the buffer material layer 153M and the silver alloy material layer 151M may be moved out of the sputtering apparatus SPU1. Therefore, the silver alloy material layer 151M will be exposed to the air. Next, the partial structure of the pixel array substrate having the buffer material layer 153M and the silver alloy material layer 151M is transmitted to a sputtering apparatus SPU2 to form the protective material layer 155M covering the silver alloy material layer 151M by using the ITO target TAR3.

Referring to FIGS. 7, 5C, and 5D, next, step S30′ is performed. In step S30′, the reflective material layer RFL_M in the structure of FIG. 5B is patterned to form the reflective layer RFL. Step S30′ is similar to step S30 in the first embodiment, and the first embodiment may be referred for relevant description. Therefore, the same details will not be repeated in the following.

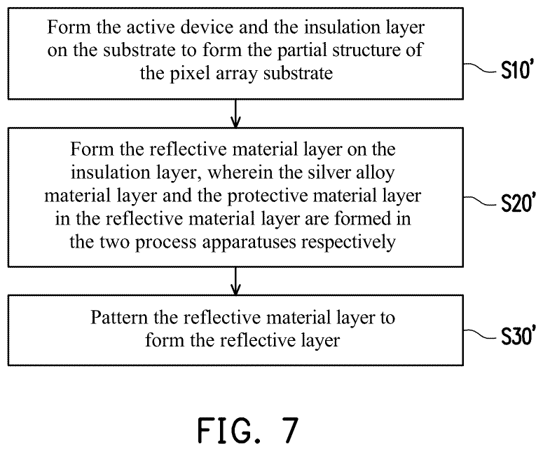

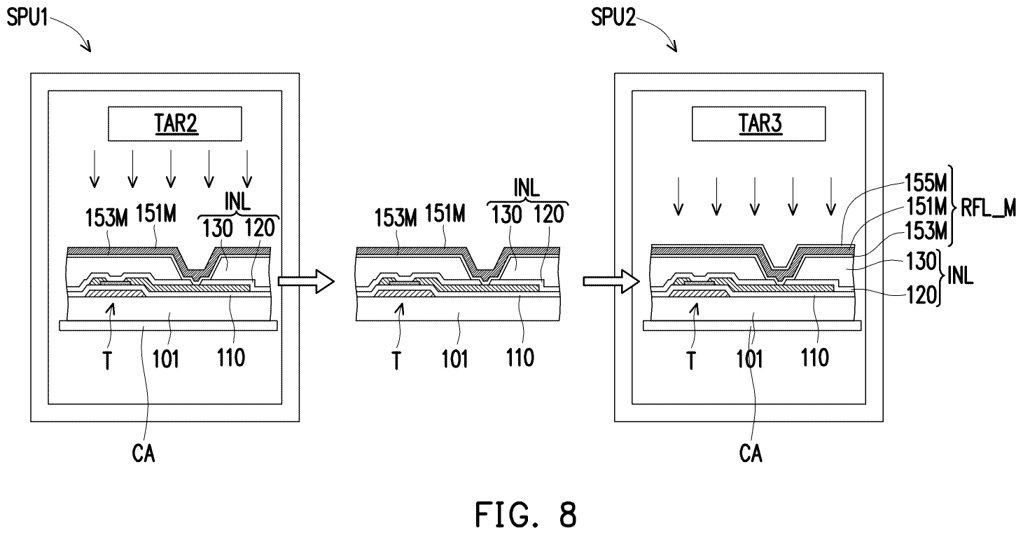

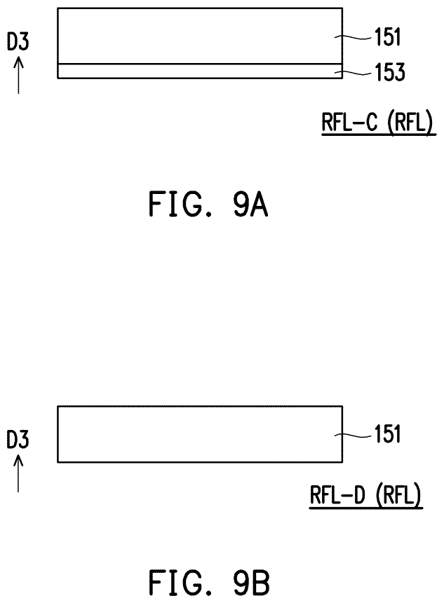

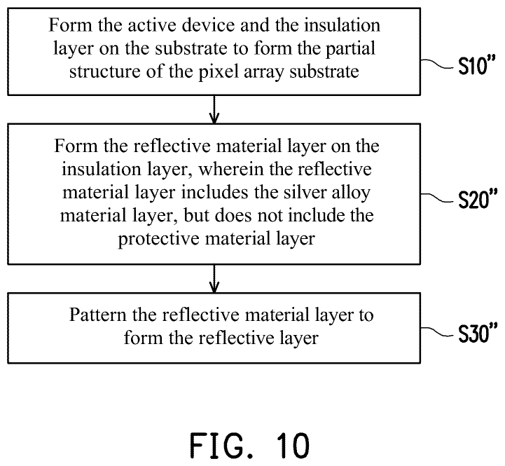

FIG. 9A is an enlarged cross-sectional view of a reflective layer of a reflective display panel according to a modified embodiment of the second embodiment of the disclosure. FIG. 9B is an enlarged cross-sectional view of a reflective layer of a reflective display panel according to another modified embodiment of the second embodiment of the disclosure. FIG. 10 is a partial flowchart of a manufacturing method of the reflective display panel having the reflective layer in FIG. 9A or 9B. FIGS. 11A to 11C are schematic views of the manufacturing method in FIG. 10.

Referring to FIGS. 9A and 9B, the reflective layer RFL of the reflective display panel

(for example, the reflective display panel 10 in FIG. 2) in this modified embodiment may be a reflective layer RFL-C in FIG. 9A or a reflective layer RFL-D in FIG. 9B. The reflective layer RFL-C in FIG. 9A includes the buffer layer 153 and the silver alloy layer 151. The reflective layer RFL-D in FIG. 9B only includes the silver alloy layer 151. The reflective layers RFL-C and RFL-D in FIGS. 9A and 9B does not include the protective layer disposed on the silver alloy layer 151 (for example, does not include the protective layer 155 in FIGS. 3A and 3B).

Referring to FIG. 10, a portion of the manufacturing method of the reflective display panel in this modified embodiment includes steps S10″ to S30″. In step S10″, the active device T and the insulation layer INL are formed on the substrate 101 to form the partial structure 100H1 of the pixel array substrate as shown in FIG. 5A. Next, the reflective layer of the reflective display panel is taken as the reflective layer RFL-C in FIG. 9A to illustrate steps S20″ and S30″. Referring to FIGS. 10 and 11A, next, step S20″ is performed. In step S20″, the reflective material layer RFL_M is formed on the insulation layer INL to form a partial structure 100H2′ of the pixel array substrate, and the reflective material layer RFL_M includes the buffer material layer 153M and the silver alloy material layer 151M. Referring to FIGS. 10, 11B, and 11C, next, step S30″ is performed. In step S30″, the reflective material layer RFL_M in a structure of FIG. 11A is patterned to form the reflective layer RFL. After the reflective material layer RFL_M is formed on the insulation layer INL in step S20″, the partial structure 100H2′ of the pixel array substrate having the reflective material layer RFL_M is removed from the sputtering apparatus to perform step S30″. Since the reflective material layer RFL_M does not have the protective material layer disposed on the silver alloy material layer 151M, the silver alloy material layer 151M will be exposed to the air before step S30″ is performed.

In the second embodiment, the silver alloy material layer 151M and the protective material layer 155M of the reflective material layer RFL_M are not manufactured in the same process apparatus. For example, after the silver alloy material layer 151M is deposited, it will be transmitted to the other process apparatus to deposit the protective material layer 155M. Therefore, the silver alloy material layer 151M will be exposed to the air when being transmitted between the process apparatuses. In the modified embodiment of the second embodiment, the reflective material layer RFL_M does not have the protective material layer disposed on the silver alloy material layer 151M. For example, after the silver alloy material layer 151M is deposited in one process apparatus, the partial structure 100H2′ of the pixel array substrate having the silver alloy material layer 151M is removed from the process apparatus to perform a patterning process on the reflective material layer RFL_M. Therefore, after the partial structure 100H2′ of the pixel array substrate is removed from the process apparatus and before the patterning process on the reflective material layer RFL_M is performed, the silver alloy material layer 151M will be exposed to the air, and during subsequent processes, the silver alloy material layer 151M that is not covered by the protective material layer and the silver alloy layer 151 that is not covered by the protective layer are easily contaminated by the subsequent processes. Therefore, in the second embodiment and the modified embodiment thereof, in addition to heat resistance, the silver alloy material layer 151M and the silver alloy layer 151 are further required to have weather resistance and tolerance in processes containing halogen and sulfur in order to withstand the pollution from the environment when being transmitted between the process apparatuses and the pollution from other processes.

In order to meet the characteristic requirements, in the second embodiment and the modified embodiment thereof, a material of the sputtering target configured to deposit the silver alloy layer 151 may include silver with an atomic percentage greater than 95% and other elements with an atomic percentage less than or equal to 5%. The other elements include at least one of zinc, antimony, and neodymium with an atomic percentage greater than or equal to 0.1% and at least one of indium, tin, palladium, and gold with an atomic percentage greater than or equal to 0.1%. That is to say, the material composition of the silver alloy material layer 151M and the silver alloy layer 151 in this embodiment and the modified embodiment thereof includes not only silver with the atomic percentage greater than 95%, but also other elements with the atomic percentage less than or equal to 5%, and the other elements include at least one of zinc, antimony, and neodymium with the atomic percentage greater than or equal to 0.1% and at least one of indium, tin, palladium, and gold with the atomic percentage greater than or equal to 0.1%.

Since a lower limit (e.g., 95%) of the atomic percentage of silver in the silver alloy material layer 151M and the silver alloy layer 151 in this embodiment and the modified embodiment thereof is lower than a lower limit (e.g., 96.5%) of the atomic percentage of silver in the silver alloy material layer 151M and the silver alloy layer 151 in the first embodiment, the reflectivity of the silver alloy layer 151 in this embodiment and the modified embodiment thereof may be slightly lower than the reflectivity of the silver alloy layer 151 in the first embodiment. Nonetheless, in this embodiment and the modified embodiment thereof, by adding non-silver elements (such as at least one of zinc, antimony, and neodymium and at least one of indium, tin, palladium, and gold) with a total atomic percentage not more than 5.0% in the silver alloy material layer 151M and the silver alloy layer 151, the weather resistance and resistance to halogen and sulfur of the silver alloy material layer 151M and the silver alloy layer 151 may be indeed effectively improved, thereby maintaining the optical properties of the silver alloy layer 151 and improving the process yield.

For example, in an embodiment, composition of the non-silver elements in the sputtering target configured to deposit the silver alloy layer 151, the silver alloy material layer 151M, and the silver alloy layer 151 includes zinc with an atomic percentage greater than or equal to 0.1% and less than or equal to 1.0%, tin with an atomic percentage greater than or equal to 0.1% and less than or equal to 1.5%, at least one of antimony, neodymium, and indium with an atomic percentage greater than or equal to 0.1% and less than or equal to 1.5%, and palladium or gold with an atomic percentage greater than or equal to 0.1% and less than or equal to 1.0%.

In another embodiment, the composition of the non-silver elements in the sputtering target configured to deposit the silver alloy layer 151, the silver alloy material layer 151M, and the silver alloy layer 151 includes zinc with the atomic percentage greater than or equal to 0.1% and less than or equal to 1.0%, tin with the atomic percentage greater than or equal to 0.1% and less than or equal to 1.5%, at least one of antimony and neodymium with an atomic percentage greater than or equal to 0.1% and less than or equal to 1.5%, and palladium or gold with the atomic percentage greater than or equal to 0.1% and less than or equal to 1.0%.

In still another embodiment, the composition of the non-silver elements in the sputtering target configured to deposit the silver alloy layer 151, the silver alloy material layer 151M, and the silver alloy layer 151 includes zinc with the atomic percentage greater than or equal to 0.1% and less than or equal to 1.0%, tin with the atomic percentage greater than or equal to 0.1% and less than or equal to 1.5%, antimony with an atomic percentage greater than or equal to 0.1% and less than or equal to 1.5%, and palladium or gold with the atomic percentage greater than or equal to 0.1% and less than or equal to 1.0%.

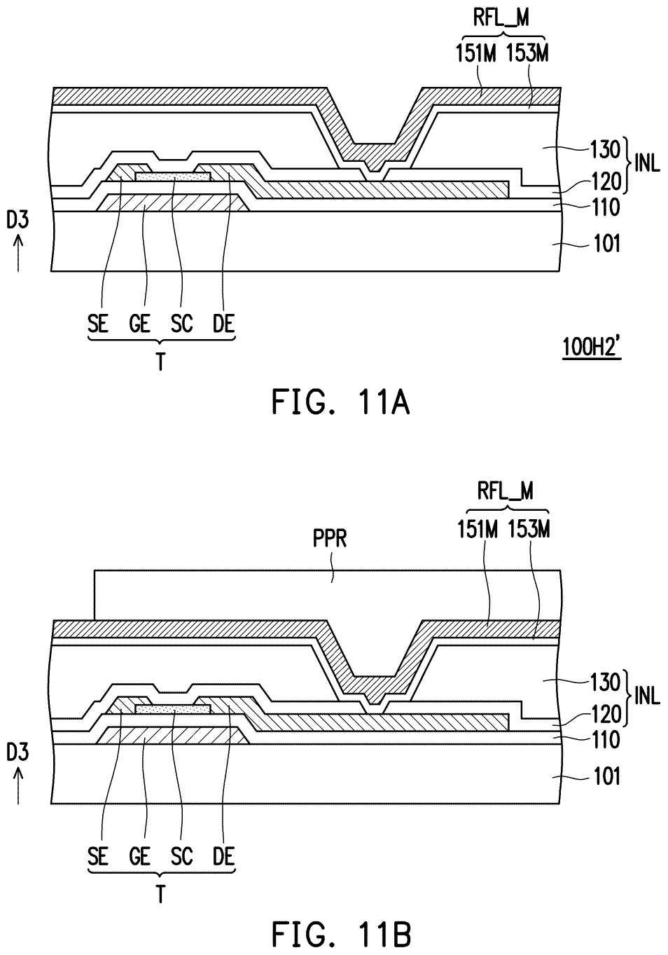

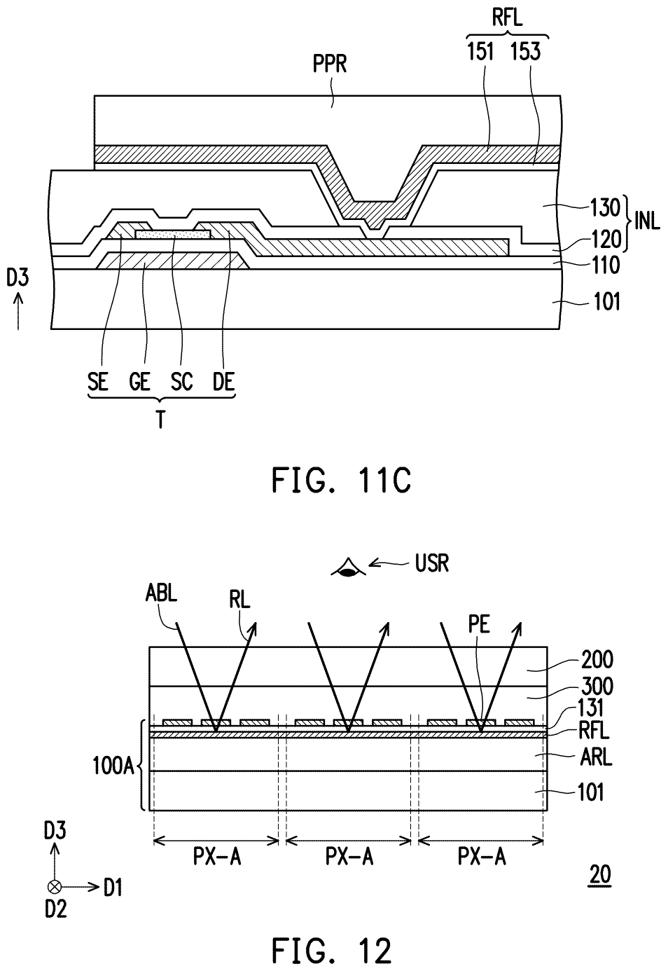

FIG. 12 is a schematic cross-sectional view of a reflective display panel according to the third embodiment of the disclosure. FIG. 13 is a schematic cross-sectional view of a pixel structure of the reflective display panel according to the third embodiment of the disclosure. Referring to FIGS. 12 and 13, a main difference between a reflective display panel 20 in this embodiment and the reflective display panel 10 in the first and second embodiments is that the pixel electrode PE of a pixel structure PX-A and the reflective layer RFL in this embodiment are different film layers, and the pixel electrode PE and the reflective layer RFL are electrically insulated from each other (that is, not electrically connected to each other).

Referring to FIG. 12, the reflective display panel 20 includes a pixel array substrate 100A. In this embodiment, the pixel array substrate 100A may include the substrate 101 and the pixel structures PX-A. The pixel structures PX-A are arranged in an array (not shown) on the substrate 101. In this embodiment, the pixel electrode PE and the reflective layer RFL of the pixel structure PX-A of the pixel array substrate 100A are different film layers. More specifically, the reflective display panel 20 further includes an insulation layer 131 covering the reflective layer RFL disposed on the flat layer 130, and the pixel electrode PE is disposed on the insulation layer 131. That is, the pixel electrode PE is disposed on the reflective layer RFL, and the insulation layer 131 is sandwiched between the pixel electrode PE and the reflective layer RFL. In addition, in this embodiment, the pixel electrode PE is electrically connected to the drain DE of the active device T through an opening OP″ of the flat layer 130 and the insulation layer 131 and the contact hole TH of the passivation layer 120. A material of the insulation layer 131 includes, for example, SiO₂, SiNₓ, SiOₓN_{y}, or Al₂O₃.

It is particularly noted that in this embodiment, the pixel electrode PE has multiple micro-slits SLT, and the micro-slits SLT overlap the reflective layer RFL. However, the disclosure is not limited thereto. For example, in this embodiment, the pixel electrode PE is a light-transmitting electrode. A material of the light-transmitting electrode includes, for example, metal oxide, such as indium tin oxide, indium zinc oxide, aluminum tin oxide, aluminum zinc oxide, other suitable oxides, or a stacked layer of at least two of the above. In this embodiment, the reflective layer RFL may also serve as a common electrode layer of the pixel structure PX-A, and the common electrode layer may receive a common potential or be grounded. However, the disclosure is not limited thereto. For example, the reflective layer RFL in FIG. 13 may also serve as the common electrode layer of the pixel structure PX-A, and the liquid crystal layer (i.e., the display medium layer 300) is driven in a fringe-field switching (FFS) mode. In some embodiments, the reflective layer RFL may be floating, and the common electrode layer (not shown) may be disposed in the pixel array substrate 100A or on the surface of the substrate 200 facing the display medium layer 300.

On the other hand, in this embodiment, the reflective layer RFL is disposed between the flat layer 130 and the insulation layer 131, and is covered by the insulation layer 131. The reflective layer RFL in this embodiment may be the reflective layer RFL-A in FIG. 3A, the reflective layer RFL-B in FIG. 3B, the reflective layer RFL-C in FIG. 9A, or the reflective layer RFL-D in FIG. 9B. However, the disclosure is not limited thereto. Similar to the first and second embodiments and the modified embodiment thereof, a method of forming the reflective layer RFL in this embodiment may be to first form a reflective material layer including a silver alloy material layer (such as the silver alloy material layer 151M in the first and second embodiments and the modified embodiment thereof), and then pattern the reflective material layer to form the reflective layer RFL. The first and second embodiments and the modified embodiment thereof may be referred for relevant description. Therefore, the same details will not be repeated in the following. In addition, in some embodiments, the pixel array substrate 100A may further include the alignment layer (not shown) disposed on the pixel electrode PE and the insulation layer 131, and the alignment layer is configured to align the liquid crystal molecules (not shown) in the liquid crystal layer (i.e., the display medium layer 300).

In this embodiment, multiple film layers are further disposed on the reflective layer RFL, such as the insulation layer 131 and the pixel electrode PE. That is, after the reflective layer RFL is formed, multiple process steps are required to be performed to form the pixel array substrate 100A. Therefore, in addition to heat resistance, the silver alloy layer 151 are further required to have weather resistance and tolerance in processes containing halogen and sulfur in order to withstand the pollution from the environment while waiting for the subsequent process steps and the impact of the subsequent process steps.

In order to meet the characteristic requirements, the elemental composition and range of the sputtering target configured to deposit the silver alloy layer 151, the silver alloy material layer, and the silver alloy layer 151 in this embodiment may be the same as the elemental composition and range of the sputtering target configured to deposit the silver alloy layer 151, the silver alloy material layer 151M, and the silver alloy layer 151 in the second embodiment and the modified embodiment thereof. Specifically, in this embodiment, the material of the sputtering target configured to deposit the silver alloy layer 151, the material of the silver alloy material layer, and the material of the silver alloy layer 151 may include silver with the atomic percentage greater than 95% and other elements with the atomic percentage less than or equal to 5%. The other elements include at least one of zinc, antimony, and neodymium with the atomic percentage greater than or equal to 0.1% and at least one of indium, tin, palladium, and gold with the atomic percentage greater than or equal to 0.1%. That is to say, the material composition of the silver alloy layer 151 in this embodiment includes not only silver with the atomic percentage greater than 95%, but also the other elements with the atomic percentage less than or equal to 5%, and the other elements include at least one of zinc, antimony, and neodymium with the atomic percentage greater than or equal to 0.1% and at least one of indium, tin, palladium, and gold with the atomic percentage greater than or equal to 0.1%.

Since the lower limit (e.g., 95%) of the atomic percentage of silver in the sputtering target configured to deposit the silver alloy layer 151, the silver alloy material layer, and the silver alloy layer 151 in this embodiment is lower than the lower limit (e.g., 96.5%) of the atomic percentage of silver in the sputtering target configured to deposit the silver alloy layer 151, the silver alloy material layer 151M, and the silver alloy layer 151 in the first embodiment, the reflectivity of the silver alloy layer 151 in this embodiment may be slightly lower than the reflectivity of the silver alloy layer 151 in the first embodiment. Nonetheless, in this embodiment, by adding the non-silver elements (such as at least one of zinc, antimony, and neodymium and at least one of indium, tin, palladium, and gold) with a total atomic percentage not more than 5.0% in the silver alloy material layer and the silver alloy layer 151, the weather resistance and resistance to halogen and sulfur of the silver alloy material layer and the silver alloy layer 151 may be indeed effectively improved, thereby maintaining the optical properties of the silver alloy layer 151 and improving the process yield.

For example, in an embodiment, the composition of the non-silver elements in the sputtering target configured to deposit the silver alloy layer, the silver alloy material layer, and the silver alloy layer 151 includes zinc with the atomic percentage greater than or equal to 0.1% and less than or equal to 1.0%, tin with the atomic percentage greater than or equal to 0.1% and less than or equal to 1.5%, at least one of antimony, neodymium, and indium with the atomic percentage greater than or equal to 0.1% and less than or equal to 1.5%, and palladium or gold with the atomic percentage greater than or equal to 0.1% and less than or equal to 1.0%.

In another embodiment, the composition of the non-silver elements in the sputtering target configured to deposit the silver alloy layer, the silver alloy material layer, and the silver alloy layer 151 includes zinc with the atomic percentage greater than or equal to 0.1% and less than or equal to 1.0%, tin with the atomic percentage greater than or equal to 0.1% and less than or equal to 1.5%, at least one of antimony and neodymium with the atomic percentage greater than or equal to 0.1% and less than or equal to 1.5%, and palladium or gold with the atomic percentage greater than or equal to 0.1% and less than or equal to 1.0%.

In still another embodiment, the composition of the non-silver elements in the sputtering target configured to deposit the silver alloy layer, the silver alloy material layer, and the silver alloy layer 151 includes zinc with the atomic percentage greater than or equal to 0.1% and less than or equal to 1.0%, tin with the atomic percentage greater than or equal to 0.1% and less than or equal to 1.5%, antimony with the atomic percentage greater than or equal to 0.1% and less than or equal to 1.5%, and palladium or gold with the atomic percentage greater than or equal to 0.1% and less than or equal to 1.0%.

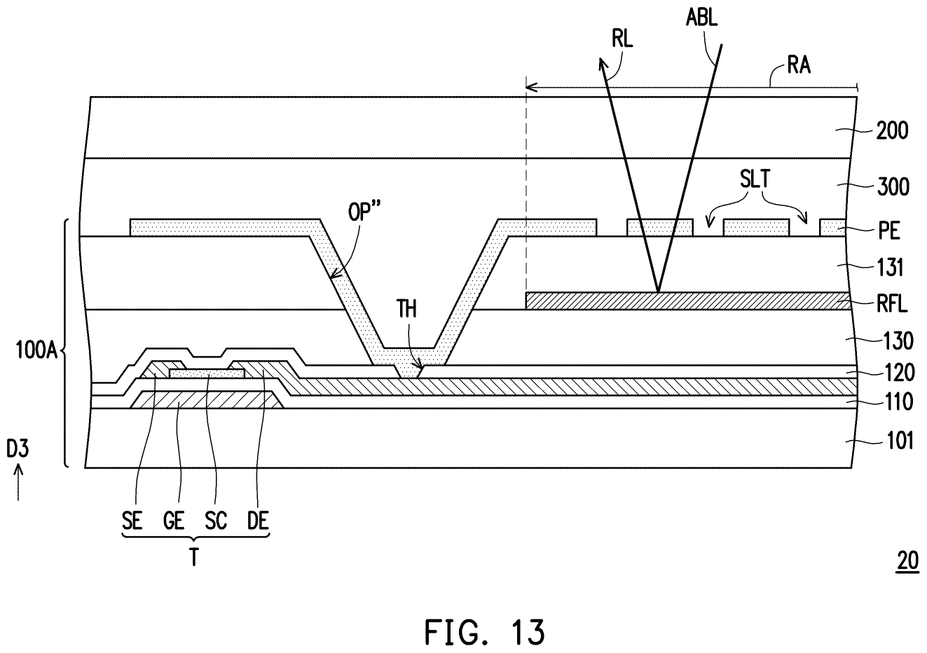

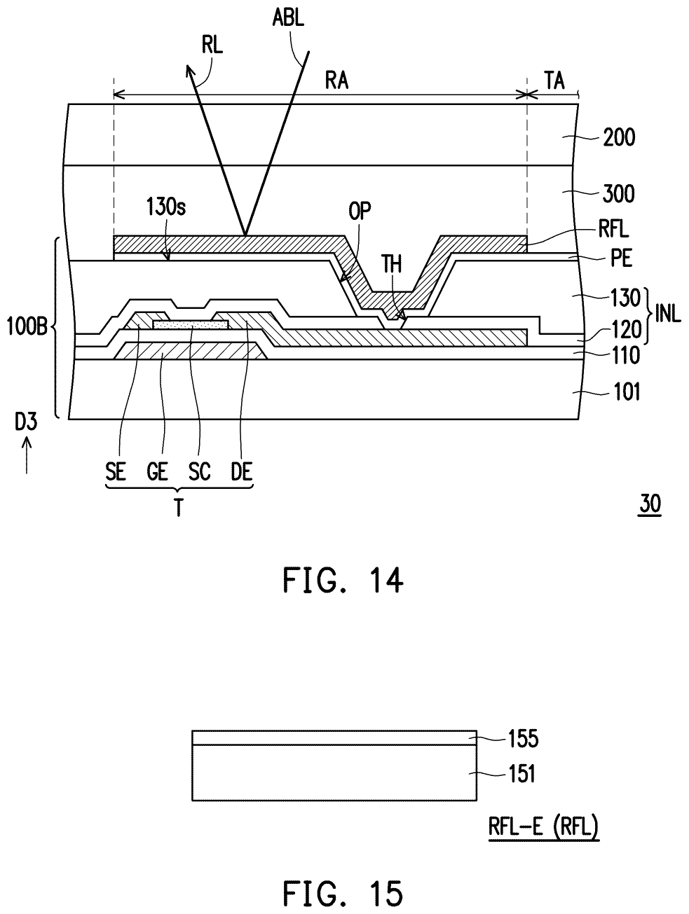

FIG. 14 is a schematic cross-sectional view of a pixel structure of a reflective display panel according to the fourth embodiment of the disclosure. FIG. 15 is an enlarged cross-sectional view of a reflective layer in FIG. 14. Referring to FIG. 14, a difference between a reflective display panel 30 in this embodiment and the reflective display panel 10 in FIG. 1 is that dispositions of the pixel electrode and the reflective layer are different. For example, in a pixel array substrate 100B in this embodiment, the pixel electrode PE of the pixel structure is, for example, the light-transmitting electrode. The material of the light-transmitting electrode includes, for example, metal oxide, such as indium tin oxide, indium zinc oxide, aluminum tin oxide, aluminum zinc oxide, other suitable oxides, or a stacked layer of at least two of the above.

That is to say, in this embodiment, the pixel electrode PE does not also serve as the reflective layer of the reflective display panel 30, and the reflective display panel 30 is required to be provided with the additional reflective layer RFL. For example, the reflective layer RFL may be disposed on the pixel electrode PE and electrically connected to the pixel electrode PE, but the disclosure is not limited thereto. In other embodiments, the reflective layer RFL may also be disposed between the pixel electrode PE and the insulation layer INL.

Specifically, in this embodiment, the reflective layer RFL is located in the reflective area RA of the pixel structure of the reflective display panel 30, and a portion of the pixel electrode PE that is not covered by the reflective layer RFL is located in a light-transmitting area TA of the pixel structure of the reflective display panel 30. That is to say, the reflective display panel 30 in this embodiment is actually a transflective display panel.

In this embodiment, the reflective layer RFL of the reflective display panel 30 may be the reflective layer RFL-D in FIG. 9B or a reflective layer RFL-E as shown in FIG. 15. The reflective layer RFL-E only includes the silver alloy layer 151 and the protective layer 155. On the other hand, in this embodiment, the pixel electrode PE is disposed between the reflective layer RFL and the insulation layer INL, and the material of the pixel electrode PE is, for example, ITO or IZO. Therefore, the pixel electrode PE may further be configured to improve the adhesion between the silver alloy layer 151 and the flat layer 130. In addition, in some embodiments, the pixel array substrate 100B may further include the alignment layer (not shown) disposed on the reflective layer RFL, the pixel electrode PE, and the insulation layer INL, and the alignment layer is configured to align the liquid crystal molecules (not shown) in the liquid crystal layer (i.e., the display medium layer 300).

In the embodiment where the reflective layer RFL of the reflective display panel 30 is the reflective layer RFL-E in FIG. 15, and the silver alloy material layer and the protective material layer that form the silver alloy layer 151 and the protective layer 155 in the reflective layer RFL-E are formed by continuous coating in the same process apparatus (such as the sputtering apparatus), the elemental composition and range of the sputtering target configured to deposit the silver alloy layer, the silver alloy material layer, and the silver alloy layer 151 may be the same as the elemental composition and range of the sputtering target configured to deposit the silver alloy layer 151, the silver alloy material layer 151M, and the silver alloy layer 151 in the first embodiment.

In the embodiment where the reflective layer RFL of the reflective display panel 30 is the reflective layer RFL-D in FIG. 9B (that is, the reflective layer RFL-D does not include the protective layer covering the silver alloy layer 151), or the embodiment where the reflective layer RFL of the reflective display panel 30 is the reflective layer RFL-E in FIG. 15, and the silver alloy material layer and the protective material layer that form the silver alloy layer 151 and the protective layer 155 in the reflective layer RFL-E are formed in the two process apparatuses respectively, the elemental composition and range of the sputtering target configured to deposit the silver alloy layer 151, the silver alloy material layer, and the silver alloy layer 151 may be the same as the elemental composition and range of the sputtering target configured to deposit the silver alloy layer 151, the silver alloy material layer 151M, and the silver alloy layer 151 in the second embodiment and the modified embodiment thereof.

Based on the above, in the reflective display panel according to an embodiment of the disclosure, the material of the sputtering target configured to deposit the reflective layer, in addition to silver with the atomic percentage greater than 96.5%, further includes zinc with the atomic percentage greater than or equal to 0.1% and less than or equal to 2.0% and antimony with the atomic percentage greater than or equal to 0.1% and less than or equal to 1.5%. Therefore, the heat resistance of the silver alloy layer deposited by the sputtering target may be significantly improved, thereby increasing the optical stability and durability of the reflective layer. In the reflective display panel according to another embodiment of the disclosure, the material of the sputtering target configured to deposit the reflective layer, in addition to silver with the atomic percentage greater than 95%, further includes other elements with the atomic percentage less than or equal to 5%. The other elements include at least one of zinc, antimony, and neodymium with the atomic percentage greater than or equal to 0.1% and at least one of indium, tin, palladium, and gold with the atomic percentage greater than or equal to 0.1%. Therefore, the silver alloy layer deposited by the sputtering target may not only significantly improve the heat resistance, but also effectively improve the weather resistance and resistance to halogen and sulfur of the silver alloy layer, thereby maintaining the optical properties of the silver alloy layer and improve the process yield.

Lastly, it is to be noted that: the embodiments described above are only used to illustrate the technical solutions of the disclosure, and not to limit the disclosure; although the disclosure is described in detail with reference to the embodiments, those skilled in the art should understand: it is still possible to modify the technical solutions recorded in the embodiments, or to equivalently replace some or all of the technical features; the modifications or replacements do not cause the essence of the corresponding technical solutions to deviate from the scope of the technical solutions of the embodiments.

What is claimed is:

1. A reflective display panel, comprising a pixel structure having a reflective area, wherein the pixel structure comprises:
an active device and an insulation layer, wherein the insulation layer is located above the active device; and
a reflective layer disposed on the insulation layer and located in the reflective area, wherein the reflective layer comprises a silver alloy layer, and a material of the silver alloy layer comprises silver with an atomic percentage greater than 96.5%, zinc with an atomic percentage greater than or equal to 0.1% and less than or equal to 2.0%, and antimony with an atomic percentage greater than or equal to 0.1% and less than or equal to 1.5%.

2. The reflective display panel according to claim 1, wherein the reflective layer further comprises:
a protective layer covering the silver alloy layer, wherein a material of the protective layer comprises a light-transmitting conductive material or a light-transmitting insulation material.

3. The reflective display panel according to claim 1, wherein the reflective layer further comprises a buffer layer sandwiched between the insulation layer and the silver alloy layer, wherein a material of the buffer layer comprises a conductive material.

4. A sputtering target adapted to deposit the silver alloy layer according to claim 1, wherein a material of the sputtering target comprises silver with the atomic percentage greater than 96.5%, zinc with the atomic percentage greater than or equal to 0.1% and less than or equal to 2.0%, and antimony with the atomic percentage greater than or equal to 0.1% and less than or equal to 1.5%.

5. A reflective display panel, comprising a pixel structure having a reflective area, wherein the pixel structure comprises:
an active device and an insulation layer, wherein the insulation layer is located above the active device; and
a reflective layer disposed on the insulation layer and located in the reflective area, wherein the reflective layer comprises a silver alloy layer, and a material of the silver alloy layer comprises silver with an atomic percentage greater than 95% and other elements with an atomic percentage less than or equal to 5%, and the other elements comprise at least one of zinc, antimony, and neodymium with an atomic percentage greater than or equal to 0.1% and at least one of indium, tin, palladium, and gold with an atomic percentage greater than or equal to 0.1%.

6. The reflective display panel according to claim 5, wherein the other elements comprise zinc with an atomic percentage greater than or equal to 0.1% and less than or equal to 1.0%, tin with an atomic percentage greater than or equal to 0.1% and less than or equal to 1.5%, at least one of antimony, neodymium, and indium with an atomic percentage greater than or equal to 0.1% and less than or equal to 1.5%, and palladium or gold with an atomic percentage greater than or equal to 0.1% and less than or equal to 1.0%.

7. The reflective display panel according to claim 6, wherein the other elements comprise zinc with the atomic percentage greater than or equal to 0.1% and less than or equal to 1.0%, tin with the atomic percentage greater than or equal to 0.1% and less than or equal to 1.5%, at least one of antimony and neodymium with the atomic percentage greater than or equal to 0.1% and less than or equal to 1.5%, and palladium or gold with the atomic percentage greater than or equal to 0.1% and less than or equal to 1.0%.

8. The reflective display panel according to claim 7, wherein the other elements comprise zinc with the atomic percentage greater than or equal to 0.1% and less than or equal to 1.0%, tin with the atomic percentage greater than or equal to 0.1% and less than or equal to 1.5%, antimony with the atomic percentage greater than or equal to 0.1% and less than or equal to 1.5%, and palladium or gold with the atomic percentage greater than or equal to 0.1% and less than or equal to 1.0%.

9. The reflective display panel according to claim 5, wherein the pixel structure further comprises:
a pixel electrode disposed above the reflective layer, wherein the pixel electrode overlaps the reflective layer; and
another insulation layer sandwiched between the pixel electrode and the reflective layer.

10. The reflective display panel according to claim 5, wherein the reflective layer further comprises:
a protective layer covering the silver alloy layer, wherein a material of the protective layer comprises a light-transmitting conductive material or a light-transmitting insulation material.

11. The reflective display panel according to claim 5, wherein the reflective layer further comprises a buffer layer sandwiched between the insulation layer and the silver alloy layer, wherein a material of the buffer layer comprises a conductive material.

12. A sputtering target adapted to deposit the silver alloy layer according to claim 5, wherein a material of the sputtering target comprises silver with the atomic percentage greater than 95% and other elements with the atomic percentage less than or equal to 5%, and the other elements comprise at least one of zinc, antimony, and neodymium with an atomic percentage greater than or equal to 0.1% and at least one of indium, tin, palladium, and gold with an atomic percentage greater than or equal to 0.1%.
